(19) United States
(12) Patent Application Publication
(10) Pub. No.: US 2020/0105312 A1
(43) Pub. Date: Apr. 2, 2020

(54) NVDIMM System with UPS power source

(71) Applicant: AgigA Tech, San Diego, CA (US)

(72) Inventors: John Matze, Carlsbad, CA (US); Cathal Phelon, Los Altos, CA (US); David Wright, San Diego, CA (US); Ronald Sartore, Valley Center, CA (US)

(21) Appl. No.: 16/147,853

(22) Filed: Sep. 30, 2018

(51) Int. Cl. G11C 5/14; G06F 1/32

(52) U.S. Cl. CPC G11C 5/141; G06F 1/3212

(57) ABSTRACT

An NVDIMM and associated power module are disclosed that enable systems in which many NVDIMMs are self-managed and supplied with backup power by an external uninterruptible power module. This removes the burden of utilizing a dedicated backup power module for the NVDIMMs.

### BACKGROUND

Non-volatile dual in-line memory module (NVDIMM) subsystems are commonly designed be used in a device-managed one-to-one configuration with an internal power module, meaning that each NVDIMM subsystem has a dedicated power module that a host device incorporating the NVDIMM subsystems manages. One example of such an arrangement is illustrated in FIG. 1.

Referring to FIG. 1, a memory system 100 includes multiple power modules 102, one power module dedicated to each of the NVDIMMs 104 in a one-to-one configuration. Each of the power modules 102 includes a power port 106 that powers one of the NVDIMMs 104.

Another common NVDIMM system utilizes a host-managed central power module on the motherboard or other component of the host system, or external to the host device, with many NVDIMMs attached to the single, common power module, either directly, or through the host device. One example of such an arrangement is illustrated in FIG. 2.

In FIG. 2 a memory system 200 comprises NVDIMMs 104 coupled to a common power module 208. The power module 208 includes a host device control port 204 coupled to a host device 202. Each of the NVDIMMs 104 are coupled to a non-management port 206. If facility power (usually AC wall power) fails, the power module 208 must provide enough energy to power the NVDIMMs 104 until they can backup (SAVE) any volatile memory contents of the host device 202 to a non-volatile memory, preserving these contents for RESTORE when the facility power comes back up.

A disadvantage of systems such as shown in FIG. 1 and FIG. 2 is that the overall system cost and complexity is increased by use of the power modules 102 or power module 208. Many host devices such as mission critical server systems utilize uninterruptible power supplies that continue to provide the host device with power when facility power fails.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a memory system 100 in accordance with one embodiment.

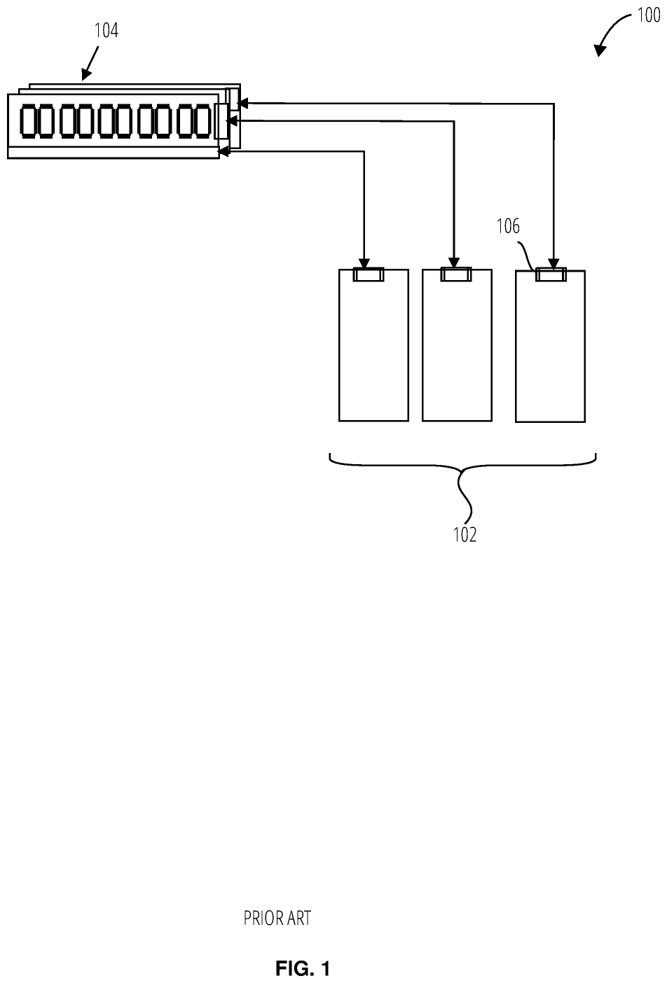

FIG. 2 illustrates a memory system 200 in accordance with one embodiment.

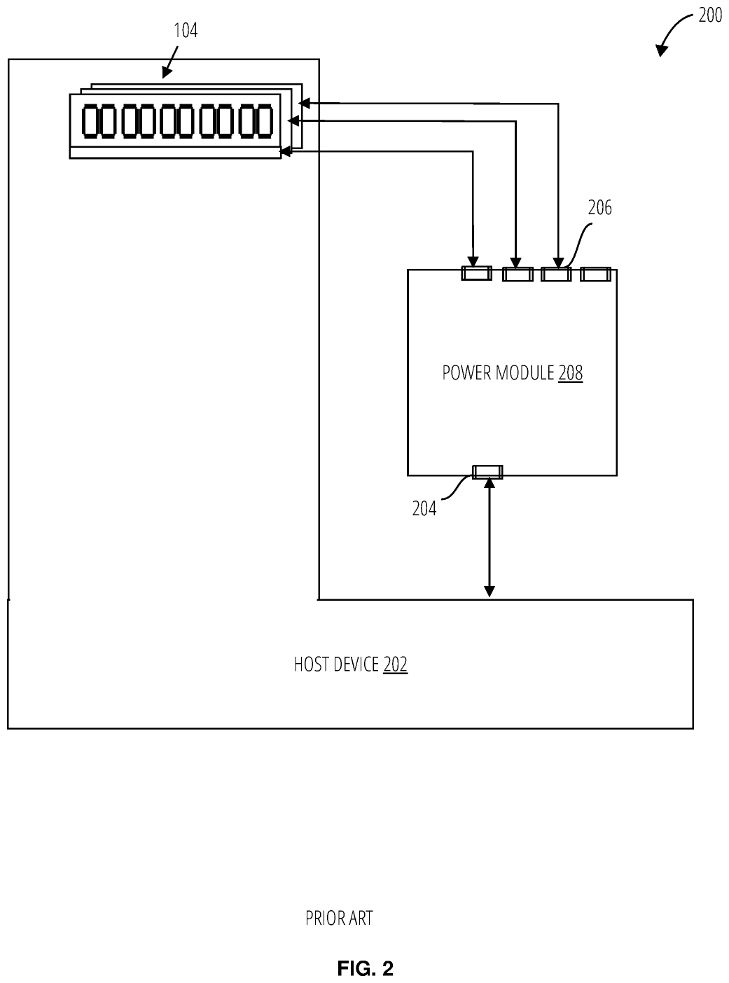

FIG. 3 illustrates a system 300 in accordance with one embodiment.

FIG. 4 illustrates an uninterruptible power supply 400 in accordance with one embodiment.

FIG. 5 illustrates a timing diagram 500 in accordance with one embodiment.

FIG. 6 illustrates a timing diagram 600 in accordance with one embodiment.

FIG. 7 illustrates a server cluster 700 in accordance with one embodiment.

FIG. 8 illustrates a host device process 800 in accordance with one embodiment.

### DETAILED DESCRIPTION

“Module” herein refers to logic packaged so as to have discrete interfaces such that logic of the module can be installed into a larger system as a set simply by installing the interfaces of the module into the larger system.

“Optional register access” herein refers to a register (hardware or virtual) address that is exposed to the host device only by management NVDIMM modules in a host device, and which is not exposed to the host device by non-management NVDIMM devices.

“Power port” herein refers to an interface on a power module into which a cable may be plugged supplying power from the power module.

“Required register access” herein refers to a register (hardware or virtual) address that is exposed to the host device by all NVDIMM modules in a host device, regardless of whether the NVDIMMs are configured as management or non-management NVDIMM devices.

Disclosed herein are embodiments of NVDIMMs and uninterruptible power supplies (UPS) to power the NVDIMMs. The host device comprising the NVDIMM(s), or the UPS, or both, comprises logic to determine whether there is sufficient stored energy to power one or more NVDIMMs long enough to ensure that a backup SAVE can be performed by each NVDIMM. Each NVDIMM may be adapted to report its SAVE power requirements to the host device and the host device or UPS then determines an aggregate SAVE power requirement for all NVDIMMs powered by the UPS.

In one embodiment the UPS's determines its stored power capacity and calculates an amount of time that it can power one or more NVDIMMs of one or more host devices. This time is reported to the connected host devices which then determine whether or not to execute in a non-volatile mode.

In one embodiment the NVDIMMs and the host device communicate and the NVDIMMs provide to the host device the operating time they require for a SAVE. The host device sends this information to the UPS. The UPS may then provide an “advanced SAVE” command alert to the host device when its internal power capacity begins to draw down to within a configured tolerance of this time. In one embodiment, the configured interval corresponds to stored energy greater than 2× the time required for the SAVE. This enables the UPS to power the NVDIMMs to perform a SAVE operation immediately, and then to perform a subsequent SAVE without recharging, in the event that facility power “bounces” off and on. This may be useful when two successive primary power losses occur in rapid succession.

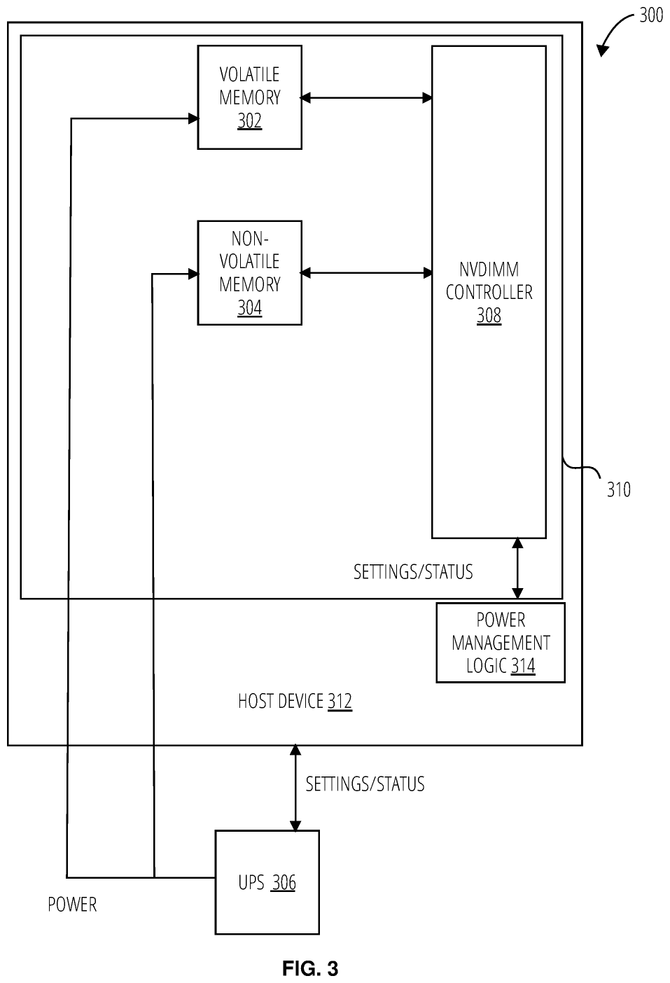

Referring to FIG. 3, a system 300 provides a low-cost, high density, non-volatile memory by using a low-cost volatile memory 302 (any volatile memory) in conjunction with a low-cost non-volatile memory 304 (any non-volatile memory). The system 300 includes, but may not be limited to, an NVDIMM 310 comprising the volatile memory 302 and non-volatile memory 304 coordinated using an NVDIMM controller 308. The NVDIMM 310 receives power and exchanges settings with an external UPS 306 via the host device 312. Other elements and/or couplings among the elements may be apparent to skilled practitioners in the relevant art(s).

The volatile memory 302 may comprise an SDRAM (Synchronous Dynamic Random Access Memory). Other types of volatile random-access memory may also be used. The nonvolatile memory may comprise a NAND FLASH, and again, other types of nonvolatile memory may be used. The host device 312 interfaces the NVDIMM 310 to the UPS 306 for power and to exchange settings, as described later, which enables the host device 312 to selectively use the NVDIMM 310 in volatile or non-volatile modes when the UPS 306 is critically depleted. When the availability of power from the UPS 306 is critically low, the host device 312 may enable the NVDIMM controller 308 to cooperate with the UPS 306 to recognize this situation.

The host device 312 may configure into a volatile mode (meaning, in the event of power failure, the contents of the volatile memory 302 will not be SAVED to the non-volatile memory 304) until the UPS 306 charges to a stored energy capacity sufficient to enable backup (SAVE) of the volatile memory 302 contents to the non-volatile memory 304. The NVDIMM controller 308 may place the host device 312 into this volatile mode. Herein, the term “SAVE” means that data of the volatile memory 302 is stored into the non-volatile memory 304. At any time, but typically after power is restored after a SAVE, the NVDIMM controller 308 may initiate restoration of backed-up data from non-volatile memory 304 to the volatile memory 302. Herein, the term “RESTORE” and “restoration” means that data of the non-volatile memory 304 is stored into the volatile memory 302.

The NVDIMM controller 308 may thus include logic to SAVE data from volatile memory 302 to non-volatile memory 304 under controlled conditions, and to RESTORE data from non-volatile memory 304 to volatile memory 302 when conditions indicate that the host device 312 can operate safely again (e.g., facility power is restored and the stored energy in the UPS 306 becomes sufficient for another backup). Note this does not mean that the host device 312 and NVDIMM 310 necessarily operate directly from facility power when available. In some implementations, the host device 312 always operates on power supplied by the UPS 306, with the UPS 306 being replenished from a facility power source while the host device 312 is operating. The NVDIMM 310 in turn receives power from the host device 312.

Those skilled in the art will appreciate that various functional components, such as the NVDIMM controller 308, and even the volatile memory 302 and non-volatile memory 304, may in fact be implemented together as one or more integrated circuit devices (e.g., a system on a Chip), or packaged as one or more discrete physical components.

Data stored within the NVDIMM 310 persists even when the power of the host device 312 fails. The host device 312 may interact with the NVDIMM 310 as though interacting with volatile memory 302 directly. In some cases, the host device 312 may “see” the volatile memory 302 as a different type of volatile memory technology than the volatile memory 302 actually is. Transparently, the data is stored internally by the NVDIMM 310 in non-volatile memory 304 persistently in the absence of power.

The NVDIMM 310 may SAVE data to non-volatile memory 304 either in the “hard” event that external power fails, or in response to a “soft” power-down command from the host device 312. Thus, the non-volatile memory 304 undergoes many fewer write cycles than would occur if it were being written every time data were written to the system 300 from the host device 312. When the non-volatile memory 304 is a low-cost, limited duty cycle NAND FLASH, the result in an extension of the useful lifetime of the non-volatile memory 304.

The NVDIMM controller 308 provides a memory interface to the host device 312. The memory interface may comprise a standard data and control interface for some particular kind of volatile memory. For example, the NVDIMM controller 308 may provide an SDRAM data, address, and control interface to the external system, even when the volatile memory 302 is not an SDRAM. The interface provided to the host device 312 may or may not be the interface for the type of volatile memory actually used by the host device 312.

The NVDIMM controller 308 may additionally provide an interface whereby the host device 312 may send commands to the NVDIMM 310 to control the NVDIMM 310 or obtain status. For example, in some embodiments the host device 312 may command the NVDIMM 310 to initiate a backup of data from volatile memory 302 to non-volatile memory 304, even though the facility power hasn't failed. Additionally or alternatively, the NVDIMM 310 or host device 312 may provide a direct user interface, such as a switch or control on a graphic user interface, whereby a user of the host device 312 may directly initiate a copy of data from volatile memory 302 to the non-volatile memory 304. Another action which may in some embodiments be initiated on the NVDIMM 310 is restoring data from non-volatile memory 304 to the volatile memory 302. In some embodiments the host device 312 may operate its system interface to the NVDIMM 310 to initiate a self-test of the system 300.

As previously described, the NVDIMM controller 308 may comprise logic to interface the volatile memory 302 to the host device 312, such as a personal computer system or a server computer system. Other examples of applications of the system 300 are embedded control applications, communications, and consumer products.

The NVDIMM controller 308 may present an interface to the host device 312, so that the volatile memory 302 is addressable for reading and writing of data by the host device 312.

Logic of the host device 312 (e.g., power management logic) may detect when power from the UPS 306 is critically low. For example, the facility housing the host device 312 may suffer a power source outage and the UPS 306 begins providing power to run the host device 312 from its battery modules. The UPS 306 may reach a point where it can no longer provide sufficient power to run the host device 312, which then shuts down. The host device 312 then shuts down, instructing the NVDIMM 310 to perform a SAVE before doing so (“soft” power down command). When facility power is restored, the UPS 306 may begin providing power to the host device 312 again, acting as a conduit of facility power to the host device 312 when the facility power comes back on. However, for some period of time after the facility power is back on, the UPS 306 may not have recharged with enough stored energy to power the backup of data from the volatile memory 302 to the non-volatile memory 304 of the NVDIMM 310 (there may be more than one) in the host device 312 that it is supplying. In this case, the UPS 306 and the NVDIMM 310 may cooperate to inhibit the host device 312 from operating to produce new volatile data in the volatile memory 302 until the UPS 306 is sufficiently recharged to enable the SAVE to take place in the event the facility power fails again (so-called “volatile mode”).

In data centers and other mission-critical scenarios, the host device 312 may be one of a cluster of servers, each comprising multiple NVDIMMs. The system software (e.g., power management logic 314) of one such host device 312 of the cluster may comprise policies to initiate the backup on all host devices in the cluster. In these scenarios the UPS 306 may determine the critical level of stored power, or remaining operating time required, to power SAVES of all the NVDIMMs in all the host devices of the cluster. In one embodiment, this determination is based modeling of background power consumption of the host devices in the cluster when facility power is present.

The NVDIMM controller 308 may also comprise logic to emulate to the host device 312 a type of volatile memory other than the actual type of the volatile memory. For example, internally the system 300 may employ SDRAM for the volatile memory 302. However, the NVDIMM controller 308 may include logic to emulate single data rate RAM (SDRAM), double data rate RAM (DDRAM), DDR2, asynchronous SRAM, C-F card, or PCI-Express (among other examples) to the host device 312.

Some or all of the components of the NVDIMM 310 may implemented in various ways. For example, these components may be implemented as one of a multi-chip set, a board subsystem, or even a single chip.

Backups and restores of data may be implemented as data moves from the volatile memory 302 to the non-volatile memory 304, and vice versa, via the NVDIMM controller 308. In other embodiments, backups and restores may be implemented via data moves from the volatile memory 302 to the non-volatile memory 304 directly, without passing through the NVDIMM controller 308 and with the NVDIMM controller 308 operating as a coordinating controller of the data backup or restore.

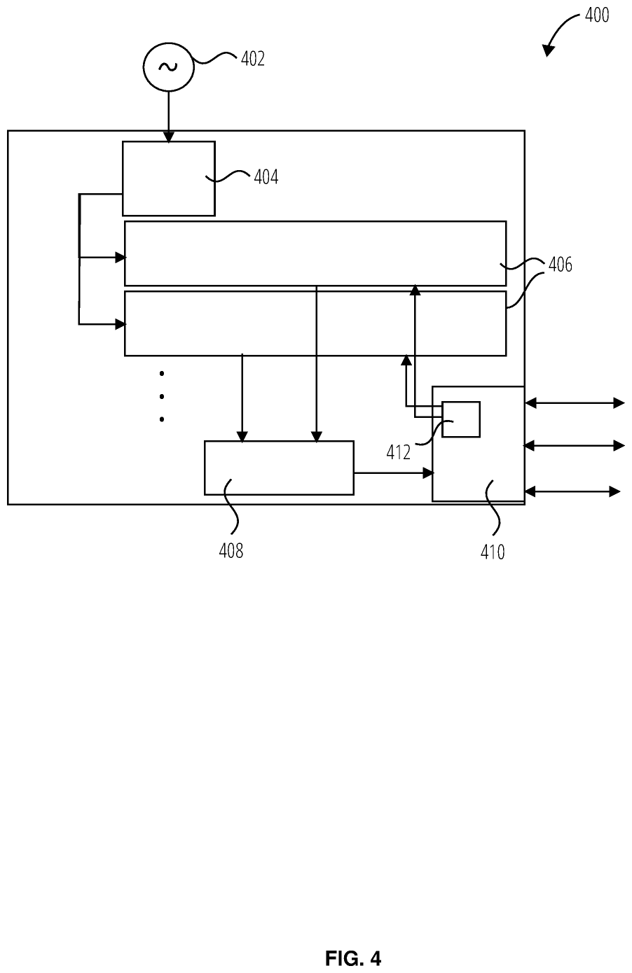

FIG. 4 illustrates an uninterruptible power supply 400 in one embodiment. The uninterruptible power supply 400 receives AC power 402 (facility power) at an internal power supply 404, which converts the AC power 402 to energy to charge one or more battery modules 406. The battery modules 406 supply an inverter 408 that converts DC power from the battery modules 406 back to AC power that is provided to one or more host devices via host device interface logic 410. This may occur both during the availability of the AC power 402 and after the AC power 402 fails in a power outage.

The uninterruptible power supply 400 may power one or more host device comprising one or more NVDIMM 310, in which case, some time after the AC power 402 fails, if the power is not restored in time, the connected host devices will shut down. At some point, the battery modules 406 will reach a point of having too little stored energy capacity to power a SAVE by one or more connected NVDIMMs for a time after the facility power is restored. The host device interface logic 410 (or some other component of the uninterruptible power supply 400) comprises a stored energy monitor 412 to track the remaining stored energy in the battery modules 406 and to signal the connected NVDIMMs when the critical threshold is reached.

The uninterruptible power supply 400 and the connected NVDIMMs may perform an initialization in which settings are conveyed to the uninterruptible power supply 400 to enable the stored energy monitor 412 to determine the critical threshold. In one embodiment an NVDIMM support-capable uninterruptible power supply 400 includes logic to determine the following operational parameters:

1) The maximum running load the uninterruptible power supply 400 supports (a measured or maximum configured value);

2) The worst-case time for all NVDIMMs that the uninterruptible power supply 400 provides backup power for to complete a SAVE;

3) The total energy requirements of all loads powered by the UPS for the duration of time needed to perform the worst-case SAVE; and

4) The current stored energy status of the uninterruptible power supply 400.

The uninterruptible power supply 400 also comprises logic to signal each of the host devices that it powers that includes an NVDIMM, indicating that the uninterruptible power supply 400 is able to support a SAVE of the NVDIMMs in the host device. Each particular host device can relay this signal to all the NVDIMMs in the particular host device to cause the NVDIMMs enter the “non-volatile mode ready” state for use by the host device.

System software (e.g., power management logic 314) running on one or more host device may receive communications from the uninterruptible power supply 400 indicating the stored power status of the uninterruptible power supply 400. When facility (AC) power fails, the system software receives indications of the remaining stored energy in the battery modules 406 and if the available capacity falls below a set policy threshold, the system software performs a controlled system shutdown of the host device (or all the host devices in a cluster of host devices). Most operating systems such as Microsoft Windows include application program interfaces to configure these shutdown policies. In one embodiment these policies are extended to enable the uninterruptible power supply 400 to interact with NVDIMMs via the host device. If the uninterruptible power supply 400 powers multiple NVDIMMs in multiple host devices, one such host device can act as the master device that oversees the shutdown policy for all the host devices, when the battery modules 406 power capacity depletes toward a critically low level. This master host device, or each host device, may perform the calculations of remaining operating time based on a reading of the remaining stored power capacity of the uninterruptible power supply 400, and monitoring of their own energy consumption requirements. In this scenario, the uninterruptible power supply 400 can simply report its remaining stored energy level to one or more of the connected host devices, and the calculation of when to perform a SAVE or shutdown is done by the host device(s).

In one embodiment, the uninterruptible power supply 400 signals supplied host devices that include NVDIMMs that it is nearing a depletion state, having calculated that it has enough stored energy (or enough remaining power supply time for its connected loads) in the battery modules 406 to support an NVDIMM SAVE for each host device. Each host device, or the uninterruptible power supply 400, may signal the NVDIMMs to initiate a power down SAVE prior to the host device shutting down.

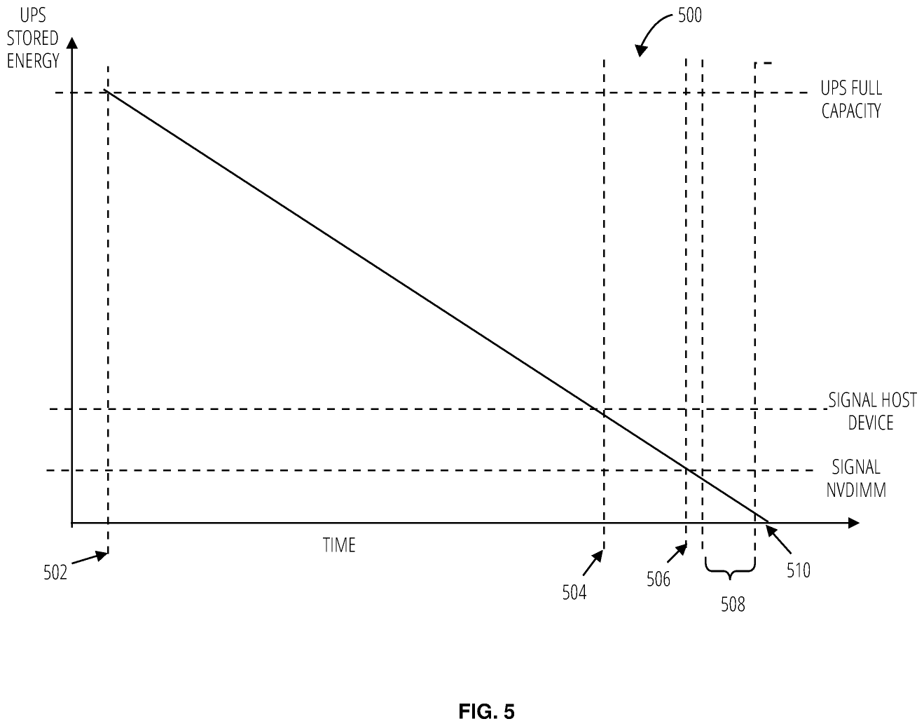

FIG. 5 illustrates a timing diagram 500 for signaling between the uninterruptible power supply 400 and the host devices and/or NVDIMMs it supplies after an AC power fail 502. After the AC power fail 502, the stored energy in the battery modules 406 of the uninterruptible power supply 400 begins being applied to power one or more host device. Some time later, the stored energy in the battery modules 406 reaches a point where it is necessary to begin host device shutdown 504. This may be in response to a signal from the UPS alerting to the depletion state, or the host device may periodically monitor the energy capacity of the UPS and detect the depletion state. Toward the end of the shutdown process, which may include the host device flushing its caches and putting the NVDIMMs into a self-refresh mode, the host device will initiate a SAVE 506 by its NVDIMMs. These SAVES must be completed within an NVDIMM SAVE time 508 before the UPS is fully depleted 510.

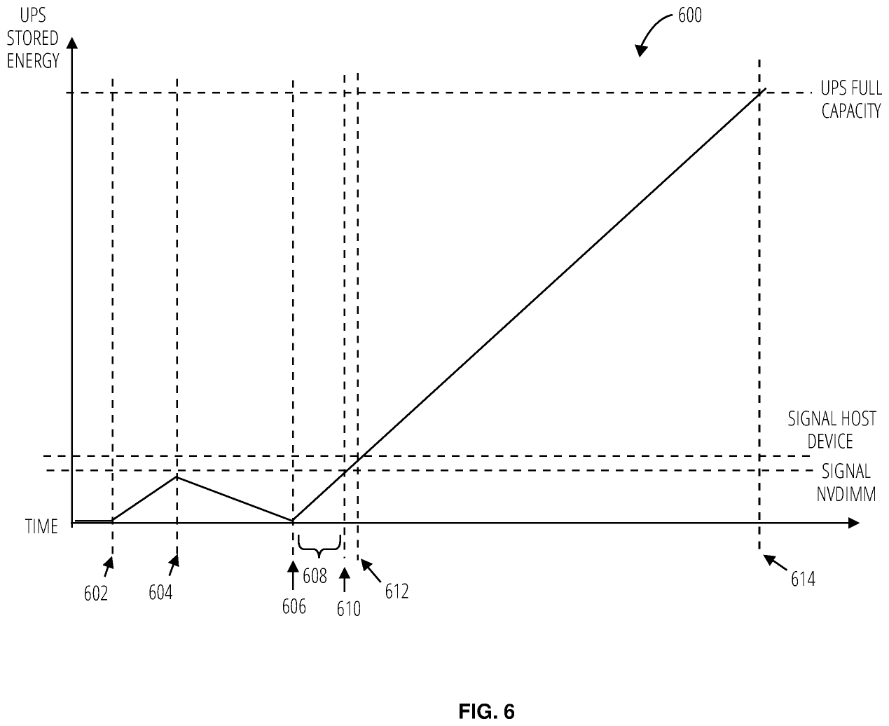

FIG. 6 illustrates a timing diagram 600 for signaling between the uninterruptible power supply 400 and the host devices and/or NVDIMMs it supplies after AC power is restored 602 subsequent to when the UPS is fully depleted 510 from a previous power fail (or when it is first deployed and uncharged). After the AC power is restored 602, the stored energy in the battery modules 406 of the uninterruptible power supply 400 begins to charge up. However before it can reach a point where the UPS stored energy is sufficient to power a SAVE (or two SAVES) 610, the AC power fails again 604. The battery modules 406 is again fully depleted, and AC power is restored again 606. The NVDIMMs perform a RESTORE from FLASH to RAM 608. Shortly thereafter, the stored energy in the battery modules 406 reaches a point where the UPS stored energy is sufficient to power a SAVE (or two SAVES) 610 by all the connected NVDIMMs.

The UPS signals the NVDIMMs via the host device (or the host device may periodically monitor the energy capacity of the UPS and detect the depletion state) of this condition. The NVDIMMs or signal the host device(s) to enable the host device(s) to enter non-volatile mode 612 (meaning, the mode in which any volatile data generated in volatile memory will be SAVED—a more robust mode of operation for the host device). If the facility power stays on, then some time later the UPS is fully charged 614.

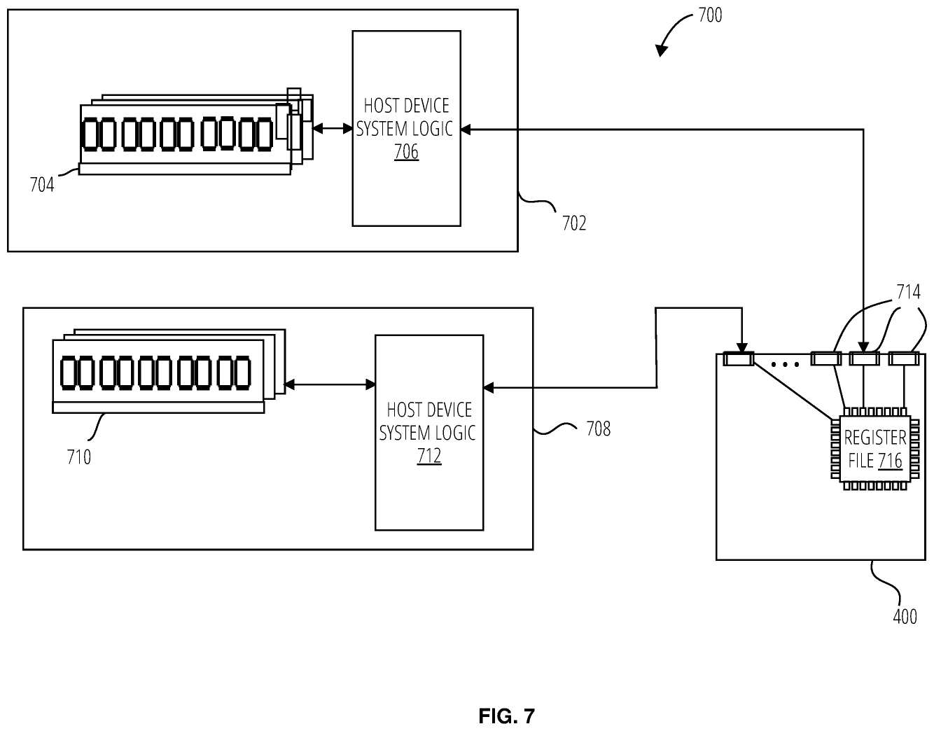

FIG. 7 illustrates an embodiment of a server cluster 700. The uninterruptible power supply 400 is coupled to a first host device 702 comprising NVDIMMs 704 and host device system logic 706, and a second host device 708 comprising NVDIMMs 710 and host device system logic 712 (additional host devices may be present as well). The NVDIMMs 704 and NVDIMMs 710 interface via the host device system logic 706 and host device system logic 712 and USB cables to the USB ports 714 of the uninterruptible power supply 400. One host device (e.g., host device 702) interacts with the uninterruptible power supply 400 on behalf of itself and the host device 708, and possible other host devices comprising NVDIMMs if present. The NVDIMMs 704 also responds to all required register access and optional register access commands from the host device that relate to the uninterruptible power supply 400. The NVDIMMs 704 and NVDIMMs 710 may provide the following settings to associated host device system logic from which it is relayed via the USB interface to the register file 716 of the uninterruptible power supply 400:

1) The worst-case time for all the NVDIMMs 704 and NVDIMMs 710, to complete a SAVE;

In one embodiment, each of the host device system logic 706 and host device 708, or only one of them if one of the host devices is designated as a management device for the server cluster 700, sends to the uninterruptible power supply 400 a minimum energy required to continue operating the host devices while performing the worst-case SAVE for all of the NVDIMMs. This may be obtained by energy consumption profiling of the host devices, or simply a preset time duration that is known to be safe. The uninterruptible power supply 400 stores these values in the register file 716 for determining when or if to signal the host devices (or only the management host device if there is one) of an impending critically low stored energy condition.

In another embodiment, these values are not communicated to the uninterruptible power supply 400, and each host device or the management host device determines when the critical stored energy level is reached. To enable this the uninterruptible power supply 400 may provide the following settings via the register file 716:

1) The maximum running load the uninterruptible power supply 400 supports (a measured or maximum configured value);

2) The current stored energy status of the uninterruptible power supply 400.

The uninterruptible power supply 400 may in some cases support both of these embodiments.

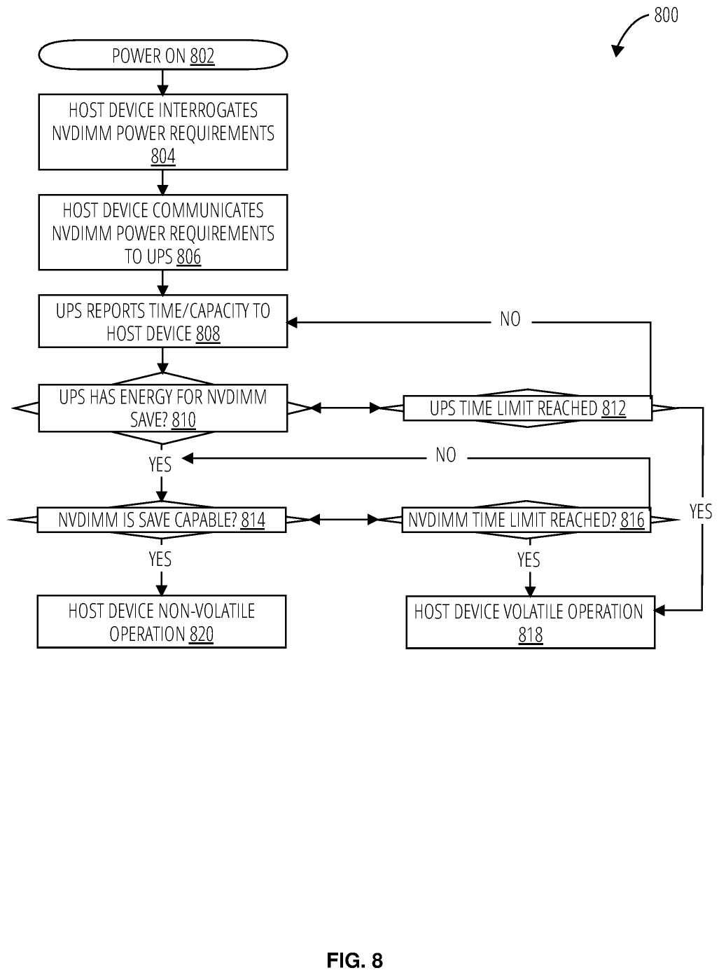

FIG. 8 illustrates a host device process 800 in one embodiment. After power on (block 802) the host device interrogates one or more NVDIMMs that it utilizes for their power requirements (block 804). The host device aggregates these requirements, and may convert them to an operating time interval based on knowledge of the host device's power consumption habits. In one embodiment, the host device communicates these requirements (possibly converted to a time interval) to the UPS (block 806). The UPS reports how much power supply time and/or power capacity is has remaining to the host device (block 808). This may be done periodically in response to requests for this information from the host device. If the UPS has enough energy or power time remaining (decision block 810 and decision block 812, as determined by the host device or the UPS), the host continues to operate. If the UPS has energy for the SAVE, the host device further confirms that the NVDIMMs are capable of performing the SAVE (decision block 814—check components are in the proper state etc.) and again checks the time limit (decision block 816). If any of these conditions is not met, the host is placed into volatile mode (block 818), otherwise, the host operates in non-volatile mode (block 820).

Terms used herein should be accorded their ordinary meaning in the relevant arts, or the meaning indicated by their use in context, but if an express definition is provided, that meaning controls.

“Circuitry” in this context refers to electrical circuitry having at least one discrete electrical circuit, electrical circuitry having at least one integrated circuit, electrical circuitry having at least one application specific integrated circuit, circuitry forming a general purpose computing device configured by a computer program (e.g., a general purpose computer configured by a computer program which at least partially carries out processes or devices described herein, or a microprocessor configured by a computer program which at least partially carries out processes or devices described herein), circuitry forming a memory device (e.g., forms of random access memory), or circuitry forming a communications device (e.g., a modem, communications switch, or optical-electrical equipment).

“Firmware” in this context refers to software logic embodied as processor-executable instructions stored in read-only memories or media.

“Hardware” in this context refers to logic embodied as analog or digital circuitry.

“Logic” in this context refers to machine memory circuits, non transitory machine readable media, and/or circuitry which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter).

“Software” in this context refers to logic implemented as processor-executable instructions in a machine memory (e.g. read/write volatile or nonvolatile memory or media).

Herein, references to “one embodiment” or “an embodiment” do not necessarily refer to the same embodiment, although they may. Unless the context clearly requires otherwise, throughout the description and the claims, the words “comprise,” “comprising,” and the like are to be construed in an inclusive sense as opposed to an exclusive or exhaustive sense; that is to say, in the sense of “including, but not limited to.” Words using the singular or plural number also include the plural or singular number respectively, unless expressly limited to a single one or multiple ones. Additionally, the words “herein,” “above,” “below” and words of similar import, when used in this application, refer to this application as a whole and not to any particular portions of this application. When the claims use the word “or” in reference to a list of two or more items, that word covers all of the following interpretations of the word: any of the items in the list, all of the items in the list and any combination of the items in the list, unless expressly limited to one or the other. Any terms not expressly defined herein have their conventional meaning as commonly understood by those having skill in the relevant art(s).

Various logic functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on.

What is claimed is:

1. A system comprising:
at least one NVDIMM; and
host device logic to retrieve a SAVE power requirement for the at least one NVDIMM and to communicate the SAVE power requirement to an uninterruptible power supply.

2. A system comprising:
a plurality of NVDIMMs; and
host device logic to retrieve a SAVE time from each of the plurality of NVDIMMs and to compute a total SAVE time requirement for the plurality of NVDIMMs, and to periodically monitor the stored energy status or remaining power time of an uninterruptible power supply, and to initiate a SAVE by the plurality of NVDIMMs when the stored energy status or remaining power time compares to a threshold energy value or time computed for operating the host device.
